(19) United States
(12) Patent Application Publication
(10) Pub. No.: US 2010/0038727 A1
(43) Pub. Date: Feb. 18, 2010

(54) Carbon-Doped Epitaxial SiGe

(75) Inventors: Srinivasan Chakravarthi, Murphy, TX (US); Periannan Chidambaram, Richardson, TX (US); Johan Weijtmans, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/582,841

(22) Filed: Oct. 21, 2009

Related U.S. Application Data
(62) Division of application No. 11/693,552, filed on Mar. 29, 2007.

(51) Int. Cl. H01L 29/78

(52) U.S. Cl. 257/408; 257/E29.255

(57) ABSTRACT

A method for forming carbon-doped epitaxial SiGe of a PMOS transistor by providing a semiconductor substrate having a PMOS transistor gate stack and recess etched active regions. The method includes forming carbon-doped epitaxial SiGe within the recess etched active regions. A PMOS transistor includes a semiconductor substrate, a PMOS transistor gate stack, and source/drain extensions. The PMOS transistor also includes carbon-doped epitaxial SiGe source/drain regions.

This is a division of application Ser. No. 11/693,552, filed Mar. 29, 2007, the entire disclosure of which is hereby incorporated by reference.

### BACKGROUND OF THE INVENTION

This invention relates to a method of forming epitaxial SiGe in PMOS transistors.

### BRIEF DESCRIPTION OF THE DRAWINGS

FIG. 1 is a cross-sectional view of a partially fabricated integrated circuit.

FIGS. 2A-2J are cross-sectional diagrams of a process for forming a PMOS transistor of an integrated circuit.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

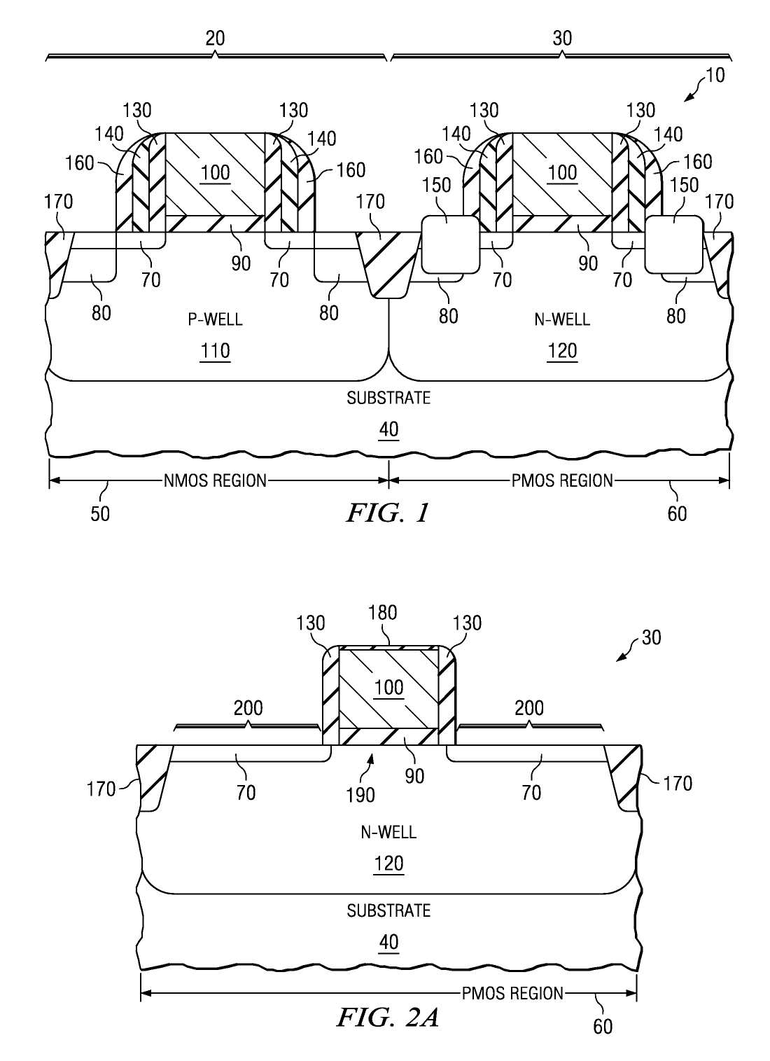

Referring to the drawings, FIG. 1 is a cross-sectional view of a partially fabricated integrated circuit 10. In the example application, the integrated circuit 10 contains CMOS transistors 20, 30 that are formed within a semiconductor substrate 40 having an NMOS region 50 and a PMOS region 60. The CMOS transistors 20, 30 are electrically insulated from other active devices (not shown) by shallow trench isolation structures 170 formed within the NMOS and PMOS regions 50, 60; however, any conventional isolation structure may be used such as field oxide regions (also known as “LOCOS” regions) or implanted isolation regions. The semiconductor substrate 40 is a single-crystalline substrate that is doped to be n-type and p-type; however, it may be a different material such as GaAs and InP and it may have additional layers. The active portion of the example CMOS transistors 20, 30 are comprised of source/drain extensions 70, source and drain regions 80, and a gate stack that is comprised of a gate oxide 90 and a gate polysilicon electrode 100.

The PMOS transistor 60 also has SiGe regions 150 that may improve transistor performance by increasing the mobility of the carriers in the channel of the PMOS transistors 30 with the intentionally created lattice mismatch that induces mechanical stress or strain across the channel region. More specifically, the compressively-strained channel typically provides an improved hole mobility that is beneficial for PMOS transistors 30 by increasing the PMOS drive current.

The PMOS transistor gate stack of FIG. 1 is created from a p-type doped polysilicon electrode 100 and a gate oxide dielectric 90. However, it is within the scope of the invention for the PMOS transistor 30 to have a metal gate electrode instead of a polysilicon gate electrode. For instance, the alternative metal gate electrode 100 may be a fully silicided polysilicon electrode that is comprised of any commonly used metal such as Ti, Ta, Ir, Mo, or any combinations thereof (including their molecules and complexes). The channel region of the PMOS transistor 30 is located within the n-well 120 directly below the gate stack.

PMOS transistor 30 is a p-channel MOS transistor formed within an n-well region 120 of the semiconductor substrate 40. Therefore, the source and drain regions 80, the SiGe regions 150, and the source/drain extensions 70 have p-type dopants. It is within the scope of the invention to have source/drain extensions 70 that are lightly doped (“LDD”), medium doped (“MDD”), or highly doped (“HDD”). The source and drain regions 80 are usually HDD.

A sidewall spacer structure comprising offset layers 130/140/160 may be used during semiconductor fabrication to enable the proper placement of the source/drain extensions 70, the SiGe regions 150, and the source/drain regions 80 respectively. In the example application, the source/drain extensions 70 are formed using the gate stack 90, 100 and the extension sidewalls 130 as a mask. Furthermore, the SiGe regions 150 are formed using the gate stack 90, 100 and the epitaxial sidewalls 140 as a mask. Moreover, the source/drain regions 80 are formed using the gate stack 90, 100 and the source/drain sidewalls 160 as a mask. However, it is within the scope of the invention to form the source/drain extensions 70 without using extension sidewalls 130 (i.e. using only the gate stack as the mask) or to form SiGe regions 150 without using epitaxial sidewalls 140 (i.e. instead reusing the extension sidewalls 130 as a mask) to eliminate process steps and thereby reduce costs and improve yield.

In an example embodiment, the SiGe region 150 is a carbon-doped epitaxial SiGe region. In an alternative embodiment, the SiGe region 150 is an epitaxial SiGe region having an initial portion (i.e. outer layer) comprised of carbon-doped epitaxial SiGe (as discussed further infra). The carbon-doped epitaxial SiGe material of both embodiments will control the out-diffusion of boron from SiGe 150 into the n-well 120. The confinement of boron within the SiGe region 150 will reduce the sheet resistance of the SiGe region 150 and thereby improve the drive current (i.e. the “ON” current) of the integrated circuit 10. Therefore, the performance of the integrated circuit may be improved by the increased ratio of the “ON” to “OFF” current resulting from the confinement of the boron dopants with the SiGe region 150.

Subsequent fabrication (not shown) will create the remainder of the ‘front-end’ portion plus the ‘back-end’ portion of the integrated circuit. The remaining front-end portion (not shown) of the integrated circuit usually contains a silicide layer that may be formed on the surface of the epi SiGe 150 and the gate electrode 100. The silicide layer facilitates an improved electrical connection between the epi SiGe 150 (or gate electrode 100) and the transistor's metal contacts that electrically connect the PMOS transistors 30 to other active or passive devices that are located throughout the integrated circuit 10. The front-end also generally contains an insulative dielectric layer that electrically insulates the metal contacts. The back-end (not shown) of the integrated circuit 10 generally contains one or more interconnect layers (and possibly one or more via layers) that properly route electrical signals and power through out the electrical devices of the completed integrated circuit.

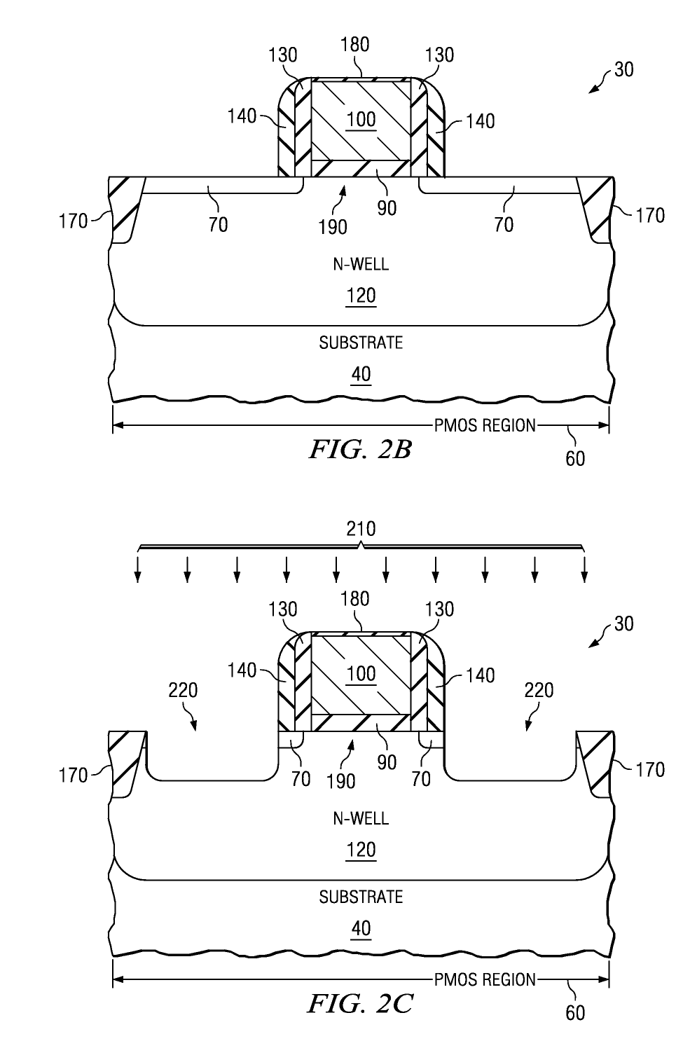

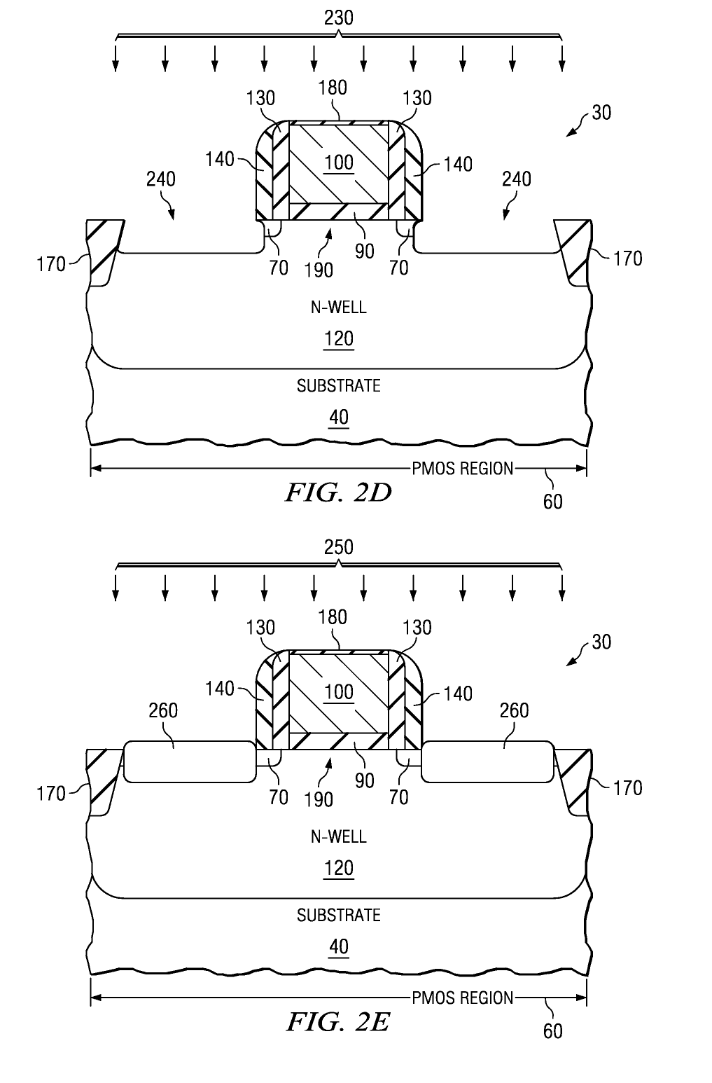

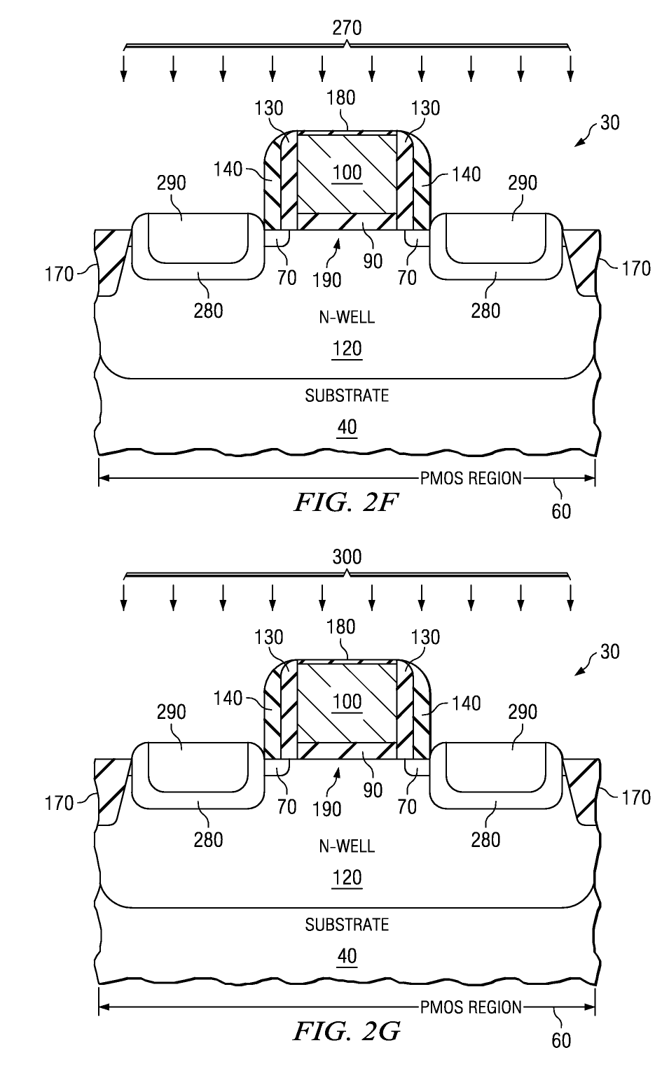

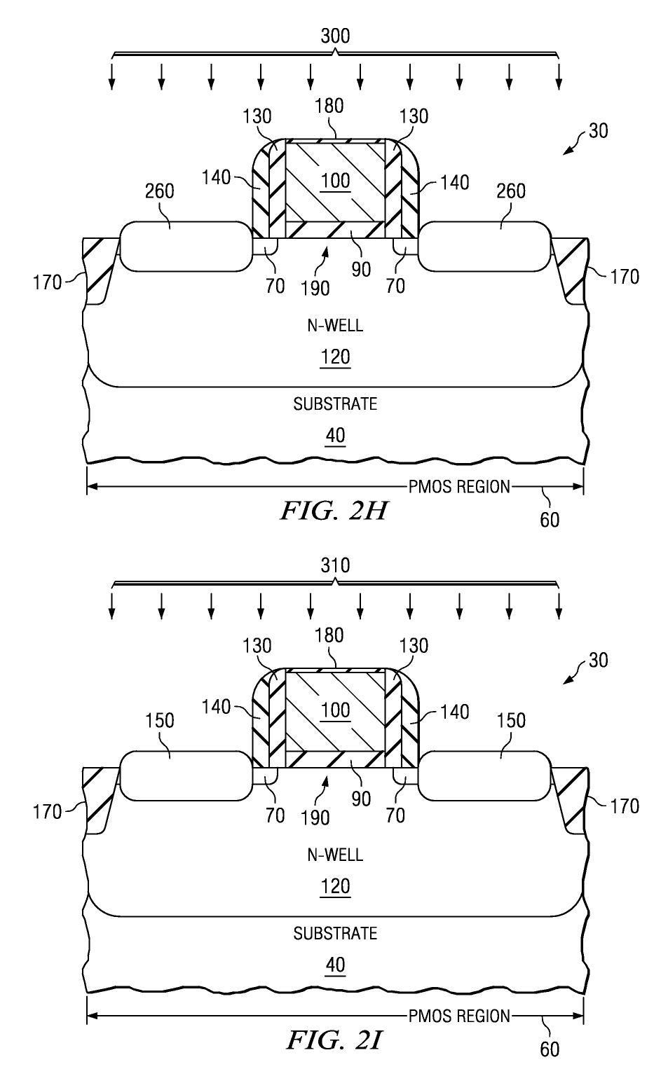

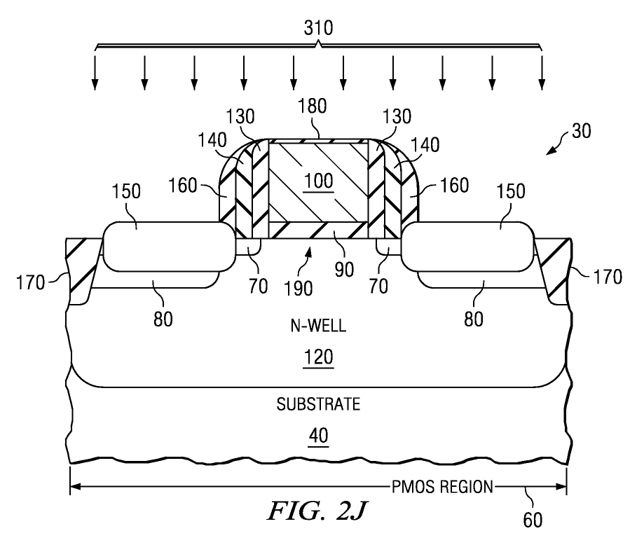

Referring again to the drawings, FIGS. 2A-2J are cross-sectional views of a partially fabricated integrated circuit that illustrate an example process for forming the PMOS transistor 30 of FIG. 1. It is within the scope of the invention to use this process to form other transistor devices that vary in some manner from the example PMOS transistor 30. For instance, the method may be used to fabricate PMOS transistors on alternative substrates such as silicon-on-insulator (“SOI”). It is to be noted that the remaining portions of the integrated circuit 10 (such as the NMOS regions 20) may be protected throughout the disclosed processes by forming a hardmask of any suitable material (such as SiN or SiON) over the regions to be protected.

FIG. 2A is a cross-sectional view of the integrated circuit 10 after the formation of an initial portion of the PMOS transistor 30. Specifically, the substrate 40 contains shallow trench isolation structures 170, the n-well 120, the gate stack 190 (containing the gate oxide 90 and the gate electrode 100), the extension sidewalls 130, and the source/drain extensions 70. However, it is within the scope of the invention to eliminate the extension sidewalls 130 by forming the source/drain extensions 70 using only the gate stack 190 as the mask. It is to be noted that the source/drain extension anneal will likely cause the lateral migration of the source/drain extensions 70 toward the channel region of the PMOS transistor 30. It is also to be noted that the exposed surfaces of the n-well 120 (i.e. the exposed surface of the source/drain extensions 70) are the active regions 200 of the PMOS transistor 30. The fabrication processes used to form the initial portion of the PMOS transistor 30 shown in FIG. 2A are those that are standard in the industry, such as the fabrication process described in the commonly assigned patent X,XXX,XXX (Ser. No. 11/184,337, TI Docket Number TI-38071, filed Jul. 19, 2005), incorporated herein by reference and not admitted to be prior art with respect to the present invention by its mention in this section.

In the example application, the gate electrode 100 is covered by an optional gate hardmask 180 comprised of SiO₂, SiN, SiON, or a combination thereof (as described further in the incorporated reference). If used, the gate hardmask 180 may protect the gate electrode 100 from undesired etching and epitaxial formation during the processes illustrated in FIGS. 2C-2F and described infra.

It is within the scope of the embodiment to also form halo implant regions within the n-well 120 (not shown). The optional halo implants (sometimes called “pocket implants” or “punch through stoppers” because of their ability to stop punch through current) may be formed with any standard implant or diffusion process within (or proximate to) the channel, the extension regions, or the source/drain regions.

As shown in FIG. 2B, epitaxial sidewalls 140 are now formed adjacent to the extension sidewalls 130. However, it is within the scope of the invention to use the extension sidewalls 130 and the gate stack 190 to form the SiGe regions 150—thereby eliminating the need to form the epitaxial sidewalls 140. If used, the thickness of the epitaxial sidewalls 140 may be adjusted to change the location of the subsequently formed SiGe regions 150 in order to obtain a targeted transistor performance based on the area of the source/drain extensions 70 that remain in the final PMOS structure. Any suitable material and process may be used to form epitaxial sidewalls 140. For instance, the epitaxial sidewalls 140 may be an oxide layer (or a nitride layer) that is formed with a chemical vapor deposition (“CVD”) process and then subsequently anisotropically etched.

The next step is the recess etch 210 of the active regions 200 of the PMOS transistor 30, as shown in FIG. 2C. Preferably, the recess etch 210 is a standard anisotropic etch of the active regions 200; therefore, a maximum amount of the previously formed doped extension regions 70 is retained within the substrate 40 after the recess etched active regions 220 are created. However, it is within the scope of the example embodiment to perform an alternative recess etch process 230 that uses a combination of anisotropic and isotropic etches—or only an isotropic etch —as shown in FIG. 2D. An isotropic etch 230 will generally undercut the extension sidewalls 130, thereby creating recess etched active regions 240 that remove more material of the extension regions 70 and also encroach closer to the channel region (causing a corresponding change in the dosing level of those extension regions 70).

It is within the scope of the invention to form recess etched active regions 220 having any suitable depth. In the example application, the recessed active regions 220 are etched to a depth between 100-1200 Å, which is greater than the depth of the source/drain extension regions 70 and approximately the same depth as the subsequently formed source and drain regions 80 (see FIG. 1).

The recess etch 210 is “selective” to the gate hardmask 180. Therefore, the gate hardmask 180 protects the gate electrode 100 of the PMOS transistor 30 from the recess etch 210. In addition, the gate hardmask 180 will protect the gate electrode 100 of the PMOS transistor 30 from forming unwanted epitaxial SiGe during the next fabrication step.

The SiGe regions 150 are now formed within the recess etched active regions 220 (or 240) of the PMOS 30. In the example applications, the SiGe 150 is either fully (e.g. element 260 of FIG. 2E) or partially (e.g. elements 280 and 290 of FIG. 2F) doped with carbon, as described more fully infra. In addition, the SiGe 150 may be doped with boron. It is within the scope of the embodiment to use any suitable process to form the epi SiGe regions 150. For example, a reduced-temperature chemical vapor deposition (“RTCVD”), an ultra-high vacuum chemical vapor deposition (“UHCVD”), a molecular beam epitaxy (“MBE”), or a small or large batch furnace-based process may be used.

In the first example application, a RTCVD process 250 is used to fill the recess etched active regions 220 (or 240) with carbon-doped epitaxial SiGe 260, as shown in FIG. 2E. Any suitable machine such as the Epsilon by ASM (Advanced Semiconductor Material) or the Centura by AMAT (Applied Materials) may be used. The example RTCVD process uses a temperature range of 450-850° C. and a pressure between 1-100 T. In addition, the RTCVD process 250 uses a silicon-bearing precursor DCS (dichlorosilane), a germanium-bearing precursor GeH₄ (germane), and a p-doping precursor B₂H₆ (diborane). Process selectivity is achieved by including HCl (hydrochloric acid) and the carrier gas H₂ (hydrogen). Moreover, the RTCVD process 250 uses a carbon-bearing precursor SiH₃CH₃ (methylsilane).

Once formed, the composition of the carbon doped epitaxial SiGe 260 will be B-doped Si₍₁₋ₓ₎Geₓ:C. The carbon doping within the carbon-doped epitaxial SiGe 260 may be any suitable concentration, such as 1e¹⁹ to 3e²⁰. However, the range of carbon concentration of the carbon-doped epitaxial SiGe 260 is preferably 5e¹⁹ to 2e²⁰.

The boron doping within the carbon-doped epitaxial SiGe 260 may be of any suitable concentration, such as 1e¹⁹ to 5e²⁰. However, the range of boron doping within the carbon-doped epitaxial SiGe 260 is preferably 1e²⁰ to 3e²⁰. It is also within the scope of the invention to form a graded concentration of boron within the carbon-doped epitaxial SiGe 260 by changing the flow of B₂H₆ while the carbon-doped epitaxial SiGe 260 is being formed. If the boron concentration is graded it will still have the same concentration ranges.

As shown in FIG. 2E, the RTCVD process 250 creates carbon-doped epitaxial SiGe regions 260 within the recess etched active regions 220 (or 240) that have a modest over-growth. Therefore, the top surfaces of the carbon-doped epitaxial SiGe regions 260 are higher than the top surface of the former active regions 200. The growth of the carbon-doped epitaxial SiGe 260 to a thickness greater than the depth of the recessed active regions 220 (or 240) can mitigate the impact of the loss of SiGe during the hardmask removal and silicidation processes that are performed later during the fabrication of the PMOS transistor 30.

In the second example application, a RTCVD process 270 is used to create an epitaxial SiGe 290 having an outer layer of carbon-doped epitaxial SiGe 280, as shown in FIG. 2F. Specifically, the carbon-bearing precursor gas SiH₃CH₃ (methylsilane) is used at the beginning of the RTCVD process 270 to form an outer carbon-doped epitaxial SiGe region 280 within the recess etched active regions 220 (or 240), and then the methylsilane gas is turned off as the RTCVD process 270 continues uninterrupted—thereby forming an inner epitaxial SiGe region 290. It is within the scope of the invention to turn off the methylsilane gas at any point during the RTCVD process 270. However, the methylsilane gas is preferably turned off when the outer layer of carbon-doped epitaxial SiGe 280 is approximately 200-300 Å thick. Once formed, the composition of the carbon-doped epitaxial SiGe 280 is B-doped Si₍₁₋ₓ)GeₓC and the composition of the epitaxial SiGe 290 is Si₍₁₋ₓ₎Geₓ.

In the example RTCVD process 270, the boron concentration is kept uniform throughout the epitaxial SiGe region 290. However, the boron concentration is either graded or uniform within the carbon-doped epitaxial SiGe region 280. More specifically, the carbon-doped epitaxial SiGe 280 may have a graded boron profile by changing the concentration of the p-doping precursor B₂H₆ (diborane) during the RTCVD process 270. For instance, the concentration of boron may be increased during the formation of the carbon-doped epitaxial SiGe 280 to facilitate a lower level of boron out-diffusion during the subsequent annealing process. Alternatively, the implantation of boron may be delayed during the formation of the carbon-doped epitaxial SiGe 280 to facilitate a lower level of boron out-diffusion during the subsequent annealing process. The concentration of boron within the carbon-doped epitaxial SiGe 280 may be between 1e¹⁹ to 5e²⁰, whether it is a graded profile or a uniform profile. However, the range of boron concentration is preferably 1e²⁰ to 3e²⁰.

The boron doping level within the epitaxial SiGe region 290 is uniform and may be of any suitable concentration, such as 5e¹⁹ to 5e²⁰. Preferably, the range of boron concentration within the epitaxial SiGe region 290 is 1e²⁰ to 3e²⁰.

As shown in FIG. 2F, the RTCVD process 270 creates epitaxial regions 280/290 that have a modest over-growth. The growth of the epitaxial regions 280/290 to a thickness greater than the depth of the recessed active regions 220 (or 240) can mitigate the impact of the loss of SiGe during the hardmask removal and silicidation processes that are performed later during the fabrication of the PMOS transistor 30.

Next, the completed epitaxial regions 260 or 280/290 are implanted with additional boron dopants using any suitable process such as ion implantation 300, as shown in FIGS. 2G and 2H. If this optional process 300 is performed, it ensures a further decrease in sheet resistance of the SiGe region 150 and a corresponding increase in the “ON” current of the device. It is within the scope of the invention to implant either B or BF₂ into the epitaxial regions 260 or 280/290. Furthermore, any suitable implant machine and any implant dosing range, such as 5e¹⁴ to 3e¹⁵ atoms per cm², may be used. Once the process 300 is complete, the semiconductor substrate is annealed with any suitable process such as RTCVD 310. The anneal process 310 will repair the damage to the semiconductor wafer and to activate the dopants—resulting in the final SiGe regions 150 shown in FIG. 21 (and also in FIG. 1).

The fabrication of the integrated circuit now continues with standard manufacturing steps. For example, the gate hardmask 180 is now removed. Then the source/drain sidewalls 160 are formed and used as a mask (with the gate stack 190) to form the source/drain regions 80, as shown in FIG. 2J. It is to be noted that the out-diffusion of boron dopants from the SiGe 150 is limited during the anneal of the source/drain regions 80 by the presence of carbon doping within the SiGe 150 as described supra.

Next, a silicide layer is formed on active silicon surfaces (such as the epitaxial SiGe 150 and the polysilicon gate electrode 100, as shown in FIG. 1). (It is to be noted that in applications where the gate electrode 100 is a metal gate electrode, the hardmask 180 would probably be left on the metal gate electrode 100 until the end of the silicidation process.) The front-end structure is completed by forming the pre-metal dielectric layer and then creating the metal contacts (within the pre-metal dielectric layer) that contact the source/drain areas 80/150 or the gate electrode 100.

The back-end fabrication includes the formation of metal vias and interconnects. Once the fabrication process is complete, the integrated circuit will be tested and packaged.

Various additional modifications to the invention as described above are within the scope of the claimed invention. For example, instead of using the carbon-bearing precursor SiH₃CH₃ (methylsilane) to form the carbon-doped epitaxial SiGe 260 or 280, other suitable carbon-bearing precursors such as SiH₂(CH₃)₂ (dimethylsilane) or SiH(CH₃)₃ (trimethylsilane) may be used. In addition, the flow of the source gases during the epitaxial refill processes 250, 270 may be controlled to alter the composition of the strain or stress producing material comprising the epitaxial regions 260, 280, 290. Furthermore, the dopants for the source/drain regions 80 may be implanted before, after, or during the formation of the epitaxial SiGe 150.

The PMOS transistor 30 may be fabricated without the use of all sidewalls 130/140/160. For example, the source/drain extensions 70 may be formed using only the gate stack 90, 100 as a mask. Alternatively, the epitaxial sidewalls 140 may be used (with the gate stack) as a mask for the formation of the source/drain regions 80 (in addition to being used to form SiGe regions 150).

Furthermore, an additional anneal process may be performed after any step in the above-described fabrication process. When used, an anneal process can improve the microstructure of materials and thereby improve the quality of the semiconductor structure. In addition, higher anneal temperatures may be used in order to accommodate transistors having thicker polysilicon gate electrodes.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A PMOS transistor, comprising:
a semiconductor substrate;
a PMOS transistor gate stack coupled to said semiconductor substrate;
source/drain extensions within said semiconductor substrate;
carbon-doped epitaxial SiGe coupled to said source/drain extensions and said semiconductor substrate; and
source/drain regions within said semiconductor substrate and coupled to said carbon-doped epitaxial SiGe.

2. The method of claim 1 wherein said carbon-doped epitaxial SiGe has boron doping.

3. The method of claim 2 wherein said carbon-doped epitaxial SiGe has a graded boron concentration.

4. The method of claim 1 wherein said PMOS transistor gate stack has a polysilicon gate electrode.

5. The method of claim 1 wherein said carbon-doped epitaxial SiGe has a carbon concentration range of 1e¹⁹ to 3e²⁰.

6. The method of claim 2 wherein said carbon-doped epitaxial SiGe has a boron concentration range of 1e²⁰ to 3e²⁰.

7. The method of claim 3 wherein said carbon-doped epitaxial SiGe has a graded boron concentration range of 1e¹⁹ to 5e²⁰.

8. A PMOS transistor, comprising:
a semiconductor substrate;
a PMOS transistor gate stack coupled to said semiconductor substrate;
source/drain extensions within said semiconductor substrate;
a layer of carbon-doped epitaxial SiGe coupled to said source/drain extensions and said semiconductor substrate;
epitaxial SiGe coupled to said layer of carbon-doped epitaxial SiGe; and
source/drain regions within said semiconductor substrate and coupled to said layer of carbon-doped epitaxial SiGe.

9. The method of claim 8 wherein said layer of carbon-doped epitaxial SiGe has boron doping.

10. The method of claim 9 wherein said layer of carbon-doped epitaxial SiGe has a graded boron concentration.

11. The method of claim 8 wherein said epitaxial SiGe has boron doping.

12. The method of claim 8 wherein said layer of carbon-doped epitaxial SiGe is less than 300 Å thick.
